(19) United States
(12) Patent Application Publication
(10) Pub. No.: US 2016/0240440 A1
(43) Pub. Date: Aug. 18, 2016

(54) SYSTEMS AND PROCESSES FOR FORMING THREE-DIMENSIONAL INTEGRATED CIRCUITS

(71) Applicant: Ultratech, Inc., San Jose, CA (US)

(72) Inventors: Arthur W. Zafiropoulo, Atherton, CA (US); Yun Wang, San Jose, CA (US); Andrew M. Hawryluk, Los Altos, CA (US)

(73) Assignee: Ultratech, Inc., San Jose, CA (US)

(21) Appl. No.: 15/141,783

(22) Filed: Apr. 28, 2016

Related U.S. Application Data
(63) Continuation of application No. 12/975,267, filed on Dec. 21, 2010.
Application No. 12/975,267 is a division of application No. 12/316,154, filed on Dec. 10, 2008, now abandoned.

(51) Int. Cl. H01L 21/822; H01L 27/06; H01L 21/02

(52) U.S. Cl. CPC H01L 21/8221; H01L 21/02532; H01L 21/02645; H01L 21/02678; H01L 27/0688

(57) ABSTRACT

Provided are systems and processes for forming a three-dimensional circuit on a substrate. A radiation source produces a beam that is directed at a substrate having an isolating layer interposed between circuit layers. The circuit layers communicate with each other via a seed region exhibiting a crystalline surface. At least one circuit layer has an initial microstructure that exhibits electronic properties unsuitable for forming circuit features therein. After being controllably heat treated, the initial microstructure of the circuit layer having unsuitable properties is transformed into one that exhibits electronic properties suitable for forming circuit feature therein. Also provided are three-dimensional circuit structures optionally formed by the inventive systems and/or processes.

### CROSS-REFERENCE TO RELATED APPLICATIONS

This application is a continuation of U.S. patent application Ser. No. 12/975,267, filed on Dec. 21, 2010 and titled “Systems and Processes for Forming Three-Dimensional Integrated Circuits,” which is a divisional of U.S. patent application Ser. No. 12/316,154, filed Dec. 10, 2008 and titled “Systems and Processes for Forming Three-Dimensional Circuits,” both of which are incorporated herein by reference in their entireties.

### BACKGROUND

1. Field of the Invention

The invention relates generally to systems and processes for forming three dimensional circuits, e.g., integrated circuits that include semiconductor circuit layers that communicate with each other. In particular, the invention relates such systems and processes that transform an initially unsuitable microstructure of a circuit layer into microstructure suitable for forming circuit features therein.

2. Description of Background Art

The performance of integrated circuits has continuously improved over time through increased speed and capability. This has primarily been achieved through the reduction of feature dimensions for microelectronic devices. Every few years, techniques have been developed to fabricate microelectronic devices with smaller dimensions, which generally produce faster integrated circuits in greater densities. In turn, devices comprised of greater quantities of faster intrinsic transistors may be produced, thereby leading to improved circuit capability.

While the benefits of faster devices with greater capability are clear, the cost for speed is correlated with increased complexity. In turn, complexity is associated with higher manufacturing costs and lower manufacturing yields. Until recently, cost metrics for the microelectronic device industry have continued to decrease primarily because manufacturing cost increases have risen slower than the physical size reductions for microelectronic devices. However, as fundamental minimum feature sizes continue to shrink, the costs for achieving these smaller features are increasing exponentially.

For example, a generally accepted metric for device capability is transistor density, the number of transistors (N) found within a unit of area. Traditionally, transistor density is measured in transistors per square micron, or N/μ². In the past, the microelectronics industry has been able to increase transistor density with the adoption of successive “technology nodes”. Each node corresponds to about a 40% decrease in linewidth and a 200% increase in transistor density. Since manufacturing cost increases associated with each successive technology node represent only about 30% per unit area, the cost metric ($/transistor) have historically decreased with each successive technology node adoption. However, the decrease in the cost metric per node is expected to reduce. In other words, the cost reductions with each new node are getting smaller. At the 32 nm node, it is expected that the manufacturing costs will begin to rise faster than the reduction in transistor density.

In particular, the cost of new lithographic tools is a significant factor in the calculation of the cost metric for microelectronic devices. For example, a state-of-the-art lithography tool in 2003 cost less than about $10 million. In contrast, a state-of-the-art tool in 2008 cost nearly $50 million. Tools such as those involving extreme ultraviolet lithography (EUVL) are expected to reach $75 million or higher in the future. As a result, the integrated circuit industry appears to be approaching an unacceptable economic condition where the fundamental cost metric ($/transistor) rises to a point that it may become unprofitable to produce devices with enhanced capability. Consequently, cost reductions on traditional products (such as memory) may stagnate because further price reductions (through feature size shrinks) will be unachievable.

Microelectronic circuits and other microstructural features are created on a substrate through the use of photolithographic technology. Typically, photolithography tools and processes are designed to image the surface of semiconductor substrates, e.g., single crystal silicon wafers, silicate glass having a polycrystalline silicon layer, etc. In turn, microelectronic devices are formed on the surface the semiconductor substrates according to the photolithographically generated images.

Once features are formed, coherent or incoherent laser technologies may be used to carry out thermal processing semiconductor-based microelectronic devices such as processors, memories and other integrated circuits (ICs) that require thermal processes. For example, the source/drain parts of transistors may be formed by exposing regions of a silicon wafer substrate to electrostatically accelerated dopants containing boron, phosphorous or arsenic atoms. However, the dopants are implanted at interstitial sites, thereby increasing crystalline defect density in the substrate. As a result, the interstitial dopants are electrically inactive and require activation through annealing.

Activation may be achieved by heating the entirety or a portion of the substrate to a particular processing temperature for a period of time sufficient for the crystal lattice to repair itself and to incorporate the impurity atoms into its structure. Typically, laser technologies are used to rapidly heat the wafer to temperatures near the semiconductor melting point to incorporate dopants at substitutional lattice sites, and the wafer is rapidly cooled to “freeze” the dopants in place.

Laser processing techniques have improved to the point where output from lasers and/or laser diodes typically are formed into a long, thin image, which in turn is quickly scanned across a surface, e.g., an upper surface of a semiconductor wafer, to heat the surface in a precisely controlled manner. For example, LTP may use a continuous or pulsed, high-power, CO₂ laser beam, which is coherent in nature. The CO₂ laser beam is raster scanned over the wafer surface so all regions of the surface are exposed to at least one pass of the heating beam. Similarly, a laser diode bar may be used to produce an incoherent beam for scanning over the wafer surface.

Although increasing transistor density has historically been achieved by increasing the number of transistors in a single surface (on the surface of a silicon wafer), it has long been recognized that a “3-D circuit” approach may be used to increase transistor density. 3-D circuits may be formed by building transistors in stacked layers. For example, 3-D circuits may be formed by depositing layers of amorphous Si onto non-Silicon layers. After deposition, the amorphous Si may be laser annealed to effect crystallization and to form large area polysilicon grains which were suitable for devices.

However, research into such three-dimensional circuits (3-D) has not been actively pursued for commercial devices because the increased costs associated with 3-D structures were higher than the costs of increasing density through lithography improvements. In addition, previous attempts at forming 3-D circuits involved melting amorphous silicon to allow it to reflow and recrystallize. Such attempts have not resulted in structures and device performance of commercial acceptability. In particular, grain sizes associated with melted and recrystallized silicon are generally too small to ensure acceptable device performance.

Thus, there is a now an unfulfilled need for systems and processes for forming three-dimensional circuits on a substrate through laser annealing techniques and related technologies.

### SUMMARY OF THE INVENTION

In a first embodiment, the invention provides a system for forming a three-dimensional circuit on a substrate. The system includes a substrate, a stage supporting the substrate and a radiation source. The substrate includes a first circuit layer, a second circuit layer, and an isolating layer interposed between the first and second circuit layers. The circuit layers communicate with each other via a seed region exhibiting a crystalline surface. The first circuit layer may have a transistor density associated with technology node approximately 32 nanometers in linewidth. The second circuit layer has an initial, e.g., amorphous, microstructure that exhibits electronic properties unsuitable for forming circuit features therein. The radiation source is adapted to heat the second circuit layer at a desired, e.g., submelt, temperature effective to initiate and propagate crystal growth from the seed region. As a result, the initial microstructure of the second circuit layer is transformed into a transformed, e.g., a crystalline, microstructure that exhibits electronic properties suitable for forming circuit features therein. Optionally, the transformed microstructure may have grain size greater than about one millimeter. Optimally, the transformed microstructure is single crystalline.

In another embodiment, the invention provides a process forming a three-dimensional circuit on a substrate. A substrate as generally described above is provided comprising a first circuit layer, a second circuit layer, and an isolating layer interposed between the first and second circuit layers. The second circuit layer is heated at a desired, e.g., submelt, temperature effective to initiate and propagate crystal growth from the seed region. As a result, the initial, e.g., amorphous, microstructure of the second circuit layer is transformed into a transformed, e.g., crystalline, microstructure that exhibits electronic properties suitable for forming circuit features therein.

For any of the embodiments of the invention, a controller may be used with a beam of radiation to effect heating. For example, when a radiation source and a stage is used, the radiation source may produce a beam for processing the second circuit layer, the stage may support and move the substrate relative to the beam, and the controller may provide relative scanning motion between the stage and the beam to allow the beam to scan over the second circuit layer. In addition, the radiation source may vary as well. For example, the radiation source may include a CO₂ laser and/or a laser diode.

Heating conditions may vary. For example, the radiation source may produce a continuous or pulsed beam that is directed by a relay toward the surface substrate at an incidence angle of at least 45°. Such a relay may form an elongate image on the substrate surface.

The structures and/or substrates of the inventions may vary as well. For example, the circuit layers and the substrate may have a substantially identical or different elemental composition, e.g., be comprised of a material selected from Si, SiGe, Ge, III-V compounds, and II-VI compounds. In particular, the seed region may vary. For example, a portion of the first circuit layer may serve as the seed region. In some instances, the seed region may be interposed between the first and second circuit layers.

In a further embodiment, the invention provides a three-dimensional circuit structure, as generally described above, that includes a first circuit layer, a second circuit layer, and an isolating layer interposed between the first and second circuit layers. The second circuit layer communicates with the first circuit layer and has circuit features formed therein or a crystalline microstructure that exhibits electronic properties suitable for forming circuit features therein.

### BRIEF DESCRIPTION OF THE DRAWINGS

FIG. 1 provides a schematic side view of an exemplary system for forming a three-dimensional circuit on a substrate.

FIGS. 2A-2M, collectively referred to as FIG. 2, depict a process for forming a three-dimensional circuit structure that includes three circuit layers.

FIG. 2A shows a bare substrate (e.g., silicon wafer) ready for the formation of circuit features therein.

FIG. 2B shows the formation of an exemplary set of transistor structures in the substrate shown in FIG. 2A.

FIG. 2C shows the deposition of a first isolation layer over the transistor structures on the substrate of FIG. 2B.

FIG. 2D shows the deposition of an optional seed region on the substrate of FIG. 2C within a through-hole that extends through the first isolation layer.

FIG. 2E shows the deposition of second circuit material on the substrate of FIG. 2D having a microstructure unsuitable for forming circuit features therein.

FIG. 2F shows the transformation of the microstructure of the second circuit layer of the substrate of FIG. 2E into a microstructure suitable for forming circuit features therein.

FIG. 2G shows a 3-D circuit structure formed as a result of the completion of the microstructural transformation shown in FIG. 2F. The 3-D circuit structure has first and second communicating circuit layers and an isolating layer interposed between the circuit layers, wherein the first circuit layers have circuit features therein and the second circuit layer has a microstructure that exhibits electronic properties suitable for forming circuit features therein.

FIG. 2H shows the 3-D structure of FIG. 2G except with circuit features in the second circuit layer.

FIG. 2I shows the 3-D structure of FIG. 2H except FIG. 2C with a second isolation layer deposited over the transistor structures of the second circuit layer.

FIG. 2J shows the 3-D structure of FIG. 2I except with an optional seed region on the second circuit layer substrate within a through-hole that extends through the second isolation layer.

FIG. 2K shows the 3-D structure of FIG. 2J except with third circuit layer material deposited over the second isolation layer, wherein the third circuit layer material has a microstructure unsuitable for forming circuit features therein.

FIG. 2L shows the 3-D structure of FIG. 2J except with third circuit layer material being transformed into one that has microstructure suitable for forming circuit features therein.

FIG. 2M shows a 3-D circuit structure having three circuit layers, each layer having circuit features formed therein.

The drawings are intended to illustrate various aspects of the invention, which can be understood and appropriately carried out by those of ordinary skill in the art. The drawings may not be to scale as certain features of the drawings may be exaggerated for emphasis and/or clarity of presentation.

### DETAILED DESCRIPTION OF THE INVENTION

### Definitions and Overview

Before describing the present invention in detail, it is to be understood that this invention, unless otherwise noted, is not limited to specific substrates, lasers, or materials, all of which may vary. It is also to be understood that the terminology used herein is for the purpose of describing particular embodiments only, and is not intended to be limiting.

It must be noted that, as used in this specification and the appended claims, the singular forms “a”, “an” and “the” include both singular and plural referents unless the context clearly dictates otherwise. Thus, for example, reference to “a beam” includes a plurality of beams as well as a single beam, reference to “a circuit feature” includes a single circuit feature and a set of circuit features, “a layer” includes one or more layers, and the like.

In describing and claiming the present invention, the following terminology will be used in accordance with the following definitions.

The term “amorphous” is used in its ordinary materials sense and describes a solid material in which there is no long-range order of the positions of the materials atoms, molecules and/or ions. An amorphous condition may be created in a solid material by cooling the material in a fluid state at a rate to faster than the rate at which the atoms can organize into a more thermodynamically favorable crystalline state.

As a related matter, the term “crystalline” is used herein in its ordinary sense and describes a solid material in which the material's atoms, molecules, and/or ions are arranged in an orderly repeating pattern extending in three spatial dimensions.

The terms “Brewster's angle” or “Brewster angle” is used to refer to the angle of incidence between a radiation beam and a surface that corresponds to the minimum or near-minimum reflectivity of the P-polarized component of the beam. Films on the surface of an object, such as a silicon wafer, may prevent it from exhibiting zero reflectivity at any angle. If, however, the films are dielectric in nature, then there generally will be an angle of minimum reflectivity for P-polarized radiation. Accordingly, the Brewster's angle as used herein for a specular surface formed from a variety of different films stacked on a substrate can be thought of as having an effective Brewster's angle, or the angle at which the reflectivity of P-polarized radiation is at a minimum. This angle of minimum reflectivity typically coincides with or is near the angle of the Brewster's angle for the substrate material.

The term “circuit feature” as used herein refers to any of a number of items that may be included in a configuration of electrically or electromagnetically connected components or devices. For example, circuit features may include resistors, capacitors, inductors, diodes, transistors, components thereof, and the like.

The term “include” and its variants, e.g., “including”, are synonymously used with the term “comprise” and its variants, e.g., “comprising” and “comprised of” unless the context of their usage clearly contraindicates such usage.

The term “intensity profile” in reference to an image or a beam refers to the distribution of the integrated radiation intensity along one or more dimensions. For example, an image may have a useful portion and a non-useful portion. The useful portion of an image typically has a “uniform” or constant integrated intensity profile over some portion of its length. In other words, the intensity profile integrated in the scan direction throughout the useful portion of the image may be substantially constant. Accordingly, any point on a substrate surface region that is scanned by a useful portion of an image having a uniform intensity profile will be heated to the same temperature. However, the intensity or intensity profile of the non-useful portion may differ from that of the useful portion. Thus, the image as a whole may have an overall “non-uniform” intensity profile even though a useful portion by itself may exhibit a uniform intensity profile.

As a related matter, the term “peak intensity region” of an image or a beam refers to the region along the beam length exhibiting the highest integrated intensity across the beam width. Typically, the entirety of the useful portion of an image will exhibit an integrated intensity very close to the peak integrated intensity.

The term “laser” is used herein in its ordinary sense and refers to a device that emits electromagnetic radiation (light) through a process called stimulated emission. Such radiation is usually, but not necessarily, spatially coherent. Typically, lasers, but not necessarily, emit electromagnetic radiation with a narrow wavelength spectrum (“monochromatic” light). The term laser is to be interpreted broadly unless its usage clearly indicates otherwise, and the interpretation may encompass, for example, gas laser, e.g., CO₂ lasers, and laser diodes.

The terms “microstructure” and “microstructural” are used in their ordinary sense from the perspective of materials scientists and refer to the structure of a material, e.g., crystallographic structure, as revealed through microscopic examination rather through naked eye observations. The terms “microstructure” and “microstructural” are not limited to structures having characteristic dimensions in the micrometer range.

The terms “optional” and “optionally” are used in their ordinary sense and means that the subsequently described circumstance may or may not occur, thus the description includes instances when the circumstance occurs and instances when it does not.

The terms “technology node” or “node” are interchangeably used herein to refer to a set of industry standards relating to line spacing and other geometric considerations associated with mass manufacture of semiconductor-based integrated circuitry in a repetitive array. In general, smaller nodes correspond to smaller line widths and greater device density. In particular, the terms describe a characteristic of feature size for microelectronics. For example, a microelectronic device of a 32 nm node may have a linewidth of approximately 32 nm.

The term “semiconductor” is used to refer to any of various solid substances having electrical conductivity greater than insulators but less than good conductors, and that may be used as a base material for computer chips and other electronic devices. Semiconductors be comprised substantially of a single element, e.g., silicon or germanium, or may be comprised of compounds such as silicon carbide, aluminum phosphide, gallium arsenide, and indium antimonide. Unless otherwise noted, the term “semiconductor” includes any one or a combination of elemental and compound semiconductors, as well as strained semiconductors, e.g., semiconductors under tension and/or compression. Exemplary indirect bandgap semiconductors suitable for use with the invention include Si, Ge, and SiC. Direct bandgap semiconductors suitable for use with the invention include, for example, GaAs, GaN, and InP.

The terms “substantial” and “substantially” are used in their ordinary sense and refer to matters that are considerably the same in importance, value, degree, amount, extent or the like.

The term “substrate” as used herein refers to any material having a surface which is intended for processing. The substrate may be constructed in any of a number of forms, for example, such as a semiconductor wafer containing an array of chips, etc.

As alluded to above, transistor density in integrated microelectronic circuits has traditionally been achieved by increasing the number of transistors in a single plane (on the surface of a silicon wafer). It has long been recognized that there is another opportunity to increasing transistor density, that is, to build transistors on top of one another, moving into the third dimension. Until recently, however, three-dimensional circuits have not been actively pursued for commercial devices because of the increased costs associated with 3-D structures were higher than the costs of increasing density through lithography improvements. This is likely to change as the costs of lithography are rising more rapidly.

In addition, most work to-date on 3-D circuits has focused on depositing layers of amorphous silicon onto a substrate. In some instances, the deposited amorphous silicon may have been laser annealed. Because the substrate may have a microstructure incompatible with that of single crystalline silicon, the annealing process resulted in the formation of polysilicon having a grain size on the order of sub-millimeters. Polysilicon of such small grain sizes are ill-suited for 3-D circuitry applications.

Thus, the invention is generally directed to systems and processes for forming a three-dimensional integrated circuit on a semiconductor, e.g., a silicon substrate. Typically, the invention involves a radiation source that produces a beam that is directed at a substrate having an isolating layer interposed between circuit layers. The circuit layers communicate with each other, electrically, physically, and/or otherwise, via a seed region exhibiting a crystalline surface. At least one circuit layer has an initial microstructure, e.g., having an amorphous or otherwise highly disorder state that exhibits electronic properties unsuitable for forming circuit features therein. After being controllably heat treated, the initial microstructure of the circuit layer is transformed into a transformed (e.g., crystalline) microstructure that exhibits electronic properties suitable for forming a circuit feature therein.

The invention is also generally directed to three-dimensional circuit structures. Optionally, such structures may be formed by the inventive systems and/or processes. Such structures typically include a first circuit layer that communicates with a second circuit layer through an isolating layer interposed between the first and second circuit layers. Each circuit layer may have a crystalline microstructure that exhibits electronic properties suitable for forming circuit features therein. Optionally, either or both layers have circuit features formed therein.

### An Exemplary System

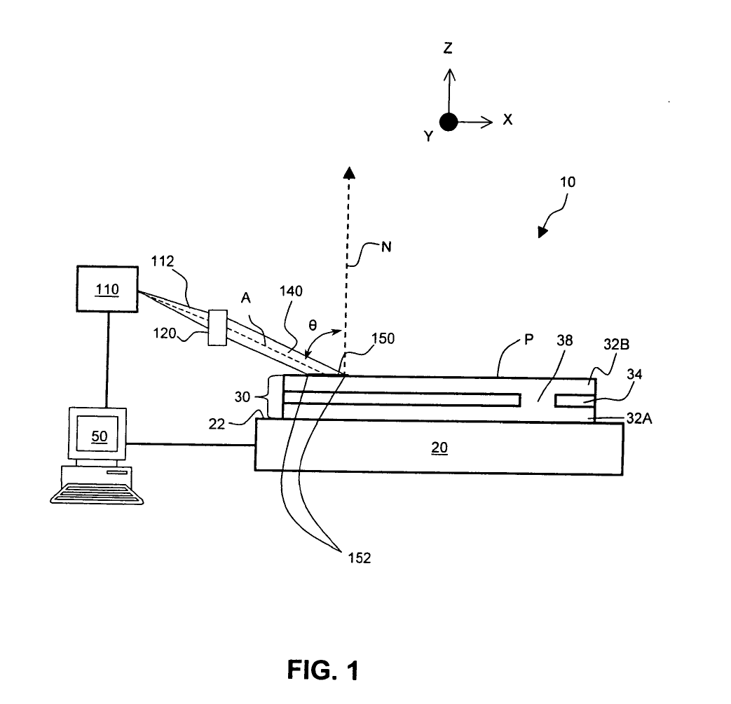

To illustrate the novel and nonobvious aspects of the invention, FIG. 1 schematically depicts an exemplary laser system 10 that may be used to carry out the invention. System 10 includes a movable substrate stage 20 having an upper surface 22 that supports a semiconductor substrate 30. Substrate 30 includes at least a first circuit layer 32A, an isolating layer 34 on the first circuit layer 32A and a second circuit layer 32B on the isolating layer 34. The first and second circuit layers communicate with each other via interface region 38 that extends through isolating layer 34. The upper surface, P, of the substrate 30 has a surface normal, N. As discussed below, the invention may involve transforming the microstructure the second circuit layer 32B from one that is unsuitable for forming circuit features therein into one that exhibits electronic properties suitable for forming a circuit feature therein.

Substrate stage 20 is operably coupled to controller 50. Substrate stage 20 is adapted to move in the X-Y plane under the operation of controller 50 so the substrate can be scanned relative to the image generated from radiation provided by radiation source 110. The stage 20 may also controllably rotate substrate 30 about an axis Z which extends orthogonally relative to the X-Y plane. As a result, the stage 20 may controllably fix or alter the orientation of substrate 30 in the X-Y plane.

The stage may include different components to carry out different functions. For example, an alignment system may be provided to position the substrate on the stage at a variable orientation angle relative to the surface normal. In such a case, the stage may independently control the substrate movement while the alignment system controls the substrate orientation.

The radiation source 110 is operably coupled to controller 50, and a relay 120 that serves to relay radiation generated by the radiation source toward the substrate to form an image on its surface. In an exemplary embodiment, radiation source 110 is a CO₂ laser that emits radiation at a wavelength λ_{H}˜10.6 μm (heating wavelength) in the form of beam 112. However, the radiation suitable for use with the invention may include LED or laser diode radiation as well, e.g., radiation having a wavelength of about 0.5 to 1.0 μm. Optionally, a plurality of radiation sources may be employed. As shown, the laser 110 generates an input beam 112 that is received by a relay 120 that is adapted to convert the input beam to an output beam 140 that forms an image 150 on the substrate.

Optionally, the intensity profile of the beam is manipulated so a portion of the image intensity is rendered uniform about its peak intensity for even heating and high energy utilization. For example, the relay 120 may transform the input beam 112 into output beam 140. The relay may be constructed in a manner to provide for desired coherent beam shaping so the output beam exhibits a uniform intensity profile over a substantial portion thereof. In short, the relay 120 and the radiation source 110 in combination may stabilize, the directionality, intensity profile, and phase profile of the output beam to produce a consistently reliable laser annealing system.

As a related matter, the term “peak intensity region” of an image or a beam refers to the region along the beam length exhibiting the highest integrated intensity across the beam width. Typically, the entirety of the useful portion of an image will exhibit an integrated intensity very close to the peak integrated intensity.

Beam 140 travels along optical axis A, which makes an angle θ with a substrate surface normal N. Typically, it is not desirable to image a laser beam on a substrate at normal incidence because any reflected light may cause instabilities when it returns to the laser cavity. Another reason for providing optical axis A at an incidence angle θ other than at normal incidence is that efficiently coupling of beam 140 into the substrate 30 may best be accomplished by judicious choice of incidence angle and polarization direction, e.g., making the incidence angle equal to the Brewster's angle for the substrate and using p-polarized radiation. In any case, the stage may be adapted to scan the substrate through the beam position while preserving or altering the incidence angle. Similarly, the stage may be adapted to control, fix or vary the orientation angle of the substrate relative to the beam.

Beam 140 forms image 150 at substrate surface P. In an exemplary embodiment, image 150 is an elongate image, such as a line image, having its lengthwise boundaries indicated at 152, and located within a plane containing the incident beam axis and the surface normal (N). Lengthwise boundaries for images having a substantially Gaussian intensity profile may represent the useful portion of the image for thermal processing. Accordingly, the incidence angle of the beam (θ) relative to the substrate surface may be measured in this plane. Surface incident angle θ may be, for example, the (effective) Brewster angle for the substrate.

The controller may be programmed to provide relative movement between the stage and the beam. Depending on the desired process parameters, the controller may provide different types of relative movement. As a result, the image 150 may be scanned along any desired path and at any desired velocity on the substrate surface to heat at least a portion of the substrate surface. Typically, as discussed below, such scanning may be initiated at the substrate surface corresponding to a seed region and carried out in a manner effective to achieve a desired temperature within a predetermined dwell time effective to transform the microstructure of the second circuit layer to exhibit electronic properties suitable for forming a circuit feature therein. Scanning may typically be performed in a direction that is orthogonal to the lengthwise axis of the image although this is not a firm requirement. Non-orthogonal and non-parallel scanning may be carried out as well.

A means may also be included to provide feedback of the uniformity when maximum temperature is achieved. Various temperature measuring means and processes may be used with the invention. For example, a detector array might be used to take a snap-shot of the emitted radiation distribution over the surface or multiple snap-shots might be used to derive a map of the maximum temperature as a function of the position across the length of the beam image. Optionally, a means for measuring the intensity profile of the beam on the substrate may be used as well.

Optimally, a real-time temperature measurement system may be employed. An exemplary temperature measurement system is described in U.S. Patent Application Publication No. 2006/0255017, entitled “Processes and Apparatus for Remote Temperature Measurement of a Specular Surface,” published on Nov. 16, 2006. Such temperature measurement systems may be used to provide input to the controller, so appropriate corrections can be made possibly by adjusting the radiation source, the relay or the scanning velocity.

### An Exemplary Process

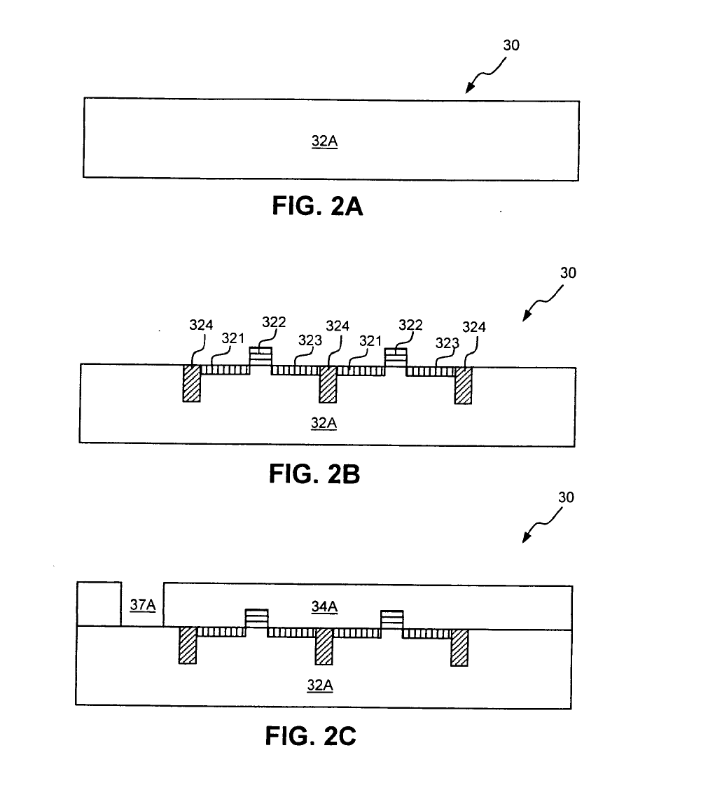

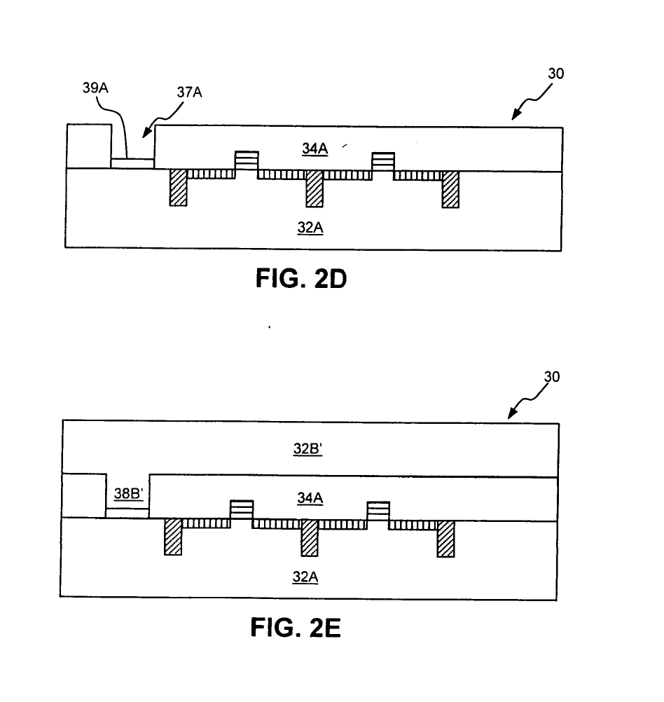

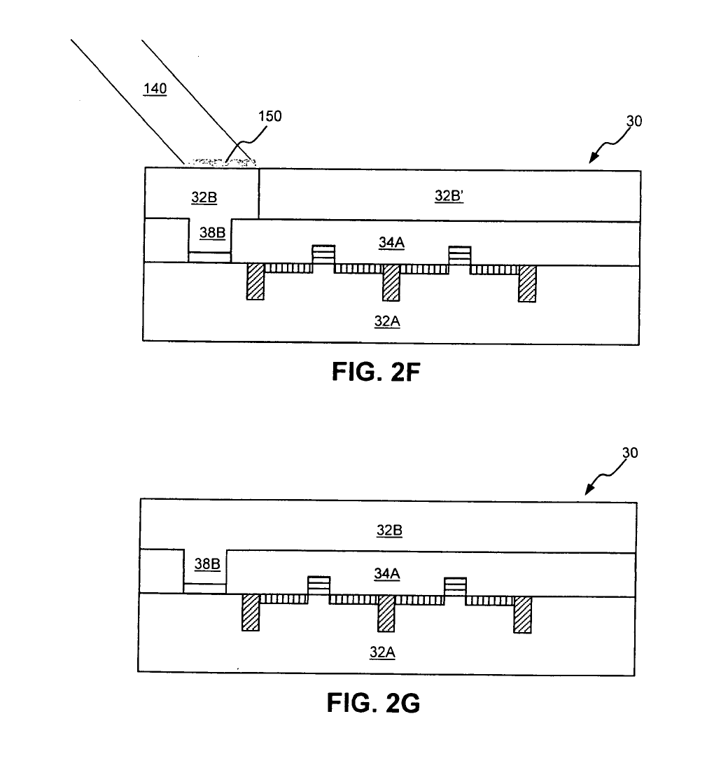

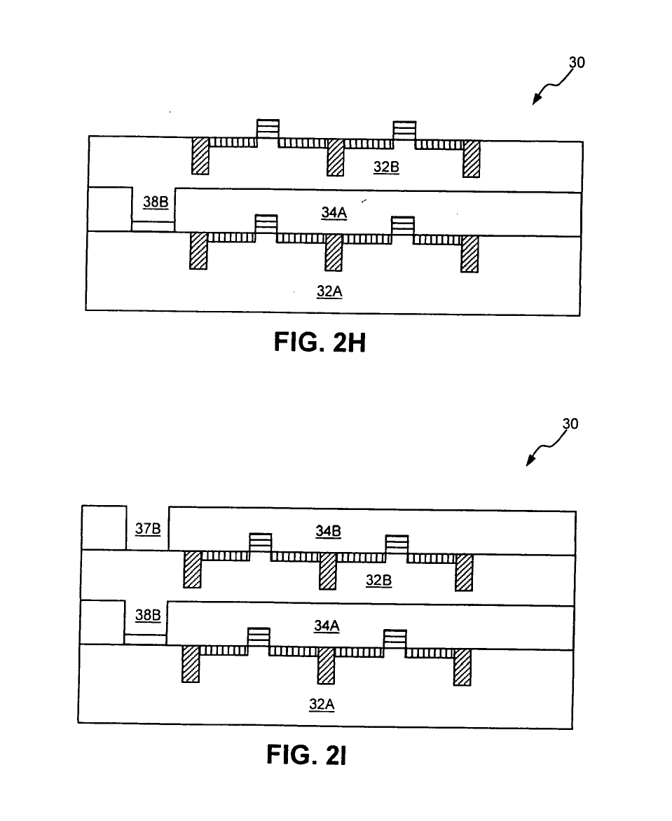

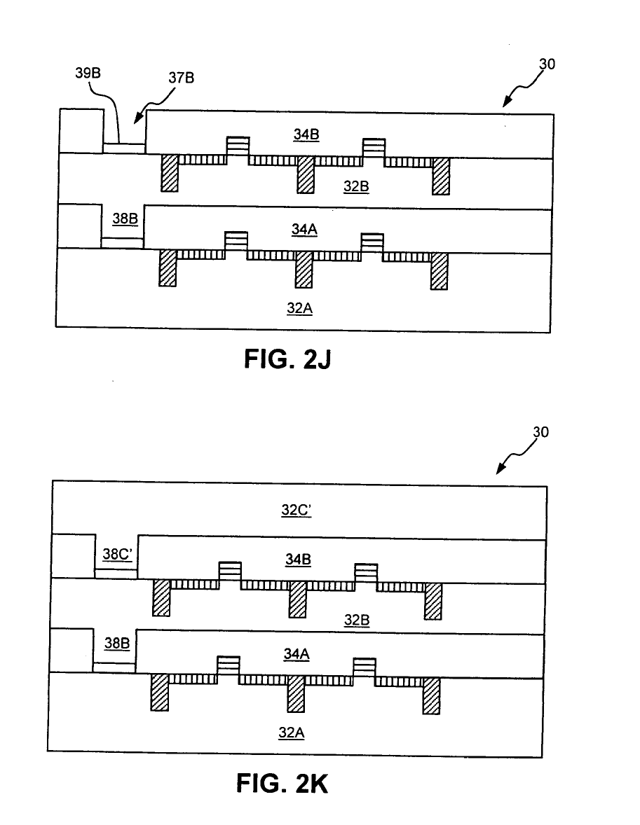

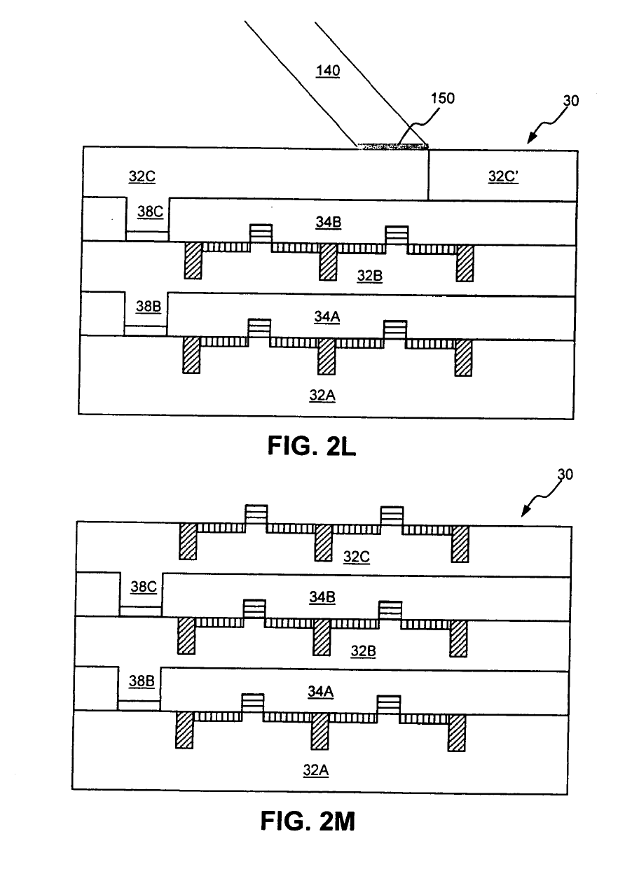

As alluded to above, the system shown in FIG. 1 may be used to carry out a process for forming a three-dimensional circuit structure. Three-dimensional circuit structures include at least two circuit layers, each having circuit features therein or at least having electronic properties suitable for forming circuit features therein. FIG. 2 depicts an exemplary process for forming a three-dimensional circuit structure having three circuit layers.

In FIG. 2A a substrate 30 is provided in which no circuit features are present. The substrate itself may serve as a first circuit layer 32A and may have a crystalline microstructure that exhibits electronic properties suitable for forming circuit features therein. For example, a circuit layer may be formed from a semiconductor wafer consisting essentially of silicon, e.g., P-doped or N-doped single crystalline silicon.

As shown in FIG. 2B, circuit features are formed in the first circuit layer 32A. The circuit features include transistors comprising source regions 32I, gate regions 322, and drain regions 323. Optional shallow trench isolation regions 324, e.g., formed from SiO₂, may serve to separate the transistors from each other.

Those of ordinary skill in the art will recognize that gate regions 322 typically have a “sandwich” structure that includes an underlying substrate material, which is a typically single crystal of semiconductor material (usually Si), a thin insulating layer (usually SiO₂), and an upper metal layer. Electrical charge, or current, can flow from the source to the drain depending on the charge applied to the gate region. The semiconductor material in the source and drain regions are “doped” with a different type of material than in the region under the gate, so an NPN or PNP type structure exists between the source and drain region of a transistor. When the source and drain regions are doped with N type material and the substrate doped with P type material, an N-channel transistor is created. Similarly, when the P-doped source and drain regions in combination with an N-doped substrate results in a P-channel transistor.

Those of ordinary skill in the art will recognize that any of various known technologies may be used to form the above circuit features. Exemplary suitable technologies include photolithography involving materials deposition techniques such as electroplating, evaporation and sputtering, as well as ion implantation, etching techniques, etc.

FIG. 2C depicts the deposition of a first isolation layer 34A on the first circuit layer 32A. As will be evident in below, the first isolation layer will be interposed between the transistor structures of the first circuit layer 32A and additional circuit features to be fabricated in subsequent circuit layers. The isolation layer 34A is typically formed from a non-conductive material. Exemplary suitable materials include single or mixed metal oxides and/or nitrides. Other non-conductive materials may be suitable as well. A first through-hole 37A extends through isolation layer 34A.

Optionally, as shown in FIG. 2D, first seed region 39A is deposited on the portion of the surface of the first circuit layer 32A that is left uncovered by first isolation layer 34 due to the presence of the first through-hole 37A. In some instances, the first seed region 39A may be deposited via epitaxial growth on the exposed surface of the first circuit layer 32A. In other instances, the exposed surface of the first circuit layer 32A in the through-hole 37A may itself serve as a seed region.

FIG. 2E depicts the deposition of a second circuit layer of an initial second circuit layer microstructure 32B′ on the isolation layer 34A and into first through-hole 37A via a planarization process. The initial microstructure 32B′, for example, may be that of amorphous silicon or any other semiconductor material. The amorphous semiconductor material is deposited so it fills first through-hole 37A and covers the first seed region 39A. As a result, first interface region 38B′ is formed over the seed first region 39A, represents a portion of the second circuit layer 32B′, and shares the initial microstructure of the second circuit layer 32B′.

However, the composition of the second circuit layer is typically substantially identical or similar to that of the first seed region 39A. Thus, for example, if the first seed region has a composition identical to that of the first circuit layer, the second circuit layer may have a composition identical to that of the first circuit layer. If, however, the first seed region has a composition different from that of the first circuit layer, the first and second circuit layers may differ in composition. In any case, when the first seed region and the second circuit layer have different compositions, the first seed region will typically exhibit a lattice spacing similar to that of the second circuit layer when transformed into one that exhibits suitable electronic properties for the formation of circuit features therein.

FIG. 2F depicts a laser beam 140 incident on the upper surface of the substrate 30 above the first seed region 39A, thereby forming image 150 on the surface. The peak intensity region of the image controllably heats and transforms initial second circuit layer microstructure 32B′ into one that renders the second circuit layer suitable for forming circuit features therein, i.e., single crystalline or large-grained polycrystalline. As the beam is scanned along the surface of the second circuit layer to allow for phase transformation to occur along the path of the beam, thereby gradually controllably converting the initial microstructure into a transformed microstructure 32B that is suitable for forming circuit features therein. A substrate 30 having a second circuit layer entirely of a transformed microstructure 32B/38B suitable for forming circuit features therein for is shown in FIG. 2G.

The controlled phase transition shown in FIGS. 2F and 2G may be carried out in a manner similar to the crystal growth techniques known in the art. For example, the Czochralski or Bridgeman methods for producing single crystalline semiconductor materials use a seed crystal to provide an ordered and substantially defect-free lattice from which ordered crystal growth may occur. As a result, uncontrolled nucleation growth of a large number of small grains may be avoided. In any case, each of these methods involves slowly and controllably cooling molten semiconductor material at the seed crystal so the seed crystal's microstructure is propagated as the molten semiconductor cools and solidifies.

The controlled phase change transformation of the present invention may be accomplished through the use of a photonic beam that subjects the initially unsuitable second circuit layer microstructure, e.g., amorphous semiconductor material, to an annealing temperature that may be either sub-melt or melt. Typically, the beam will begin the phase transformation at the “seed region”. As the beam is scanned across the substrate, care should be taken to provide the proper balance of temperature and dwell time for controlled phase transition to avoid excessive and/or inadequate heating. Excessive and/or inadequate heating may result in the presence of excessive defects, e.g., dislocations, grain boundaries, etc.

While a single crystalline microstructure is optimal for a circuit layer, it is not a necessity. The circuit layer should have a microstructure associated with sufficiently high mobility to avoid unduly compromising the performance of any circuit features formed. Thus, in the case of circuit layers with a polycrystalline semiconductor material microstructure, the average grain size of the layer should be generally greater than the size of circuit feature(s) to be formed in the circuit layers. For transistor-containing circuit layers of a polycrystalline microstructure, the average grain size should be no less than about 10 micrometers. Preferably, the average grain size should be at least 1 millimeter. However, it should be noted that grain size is only one factor that affects charge mobility. The invention is not limited to any particular grain sizes if charge mobility is adequate.

In FIG. 2H, additional circuit features are formed in the second circuit layer. As discussed above, the second circuit, formerly exhibiting a microstructure associated with electronic properties suitable for forming circuit features therein, now exhibits a microstructure associated with electronic properties suitable for forming circuit features therein. Such circuit features are generally similar to those formed in the first circuit layer, as shown in FIG. 2B. For example, the circuit features include transistors comprising source regions 32I, gate regions 322, and drain regions 323 as well as optional shallow trench isolation regions 324 as shown in FIG. 2B. The circuit features in the second circuit layer effectively doubles the transistor density on the substrate without the need for improved lithography.

FIG. 2I depicts the deposition of a second isolation layer 34B having a second through-hole 37B extending therethrough on the second circuit layer 32B in a manner analogous to the deposition of a first isolation layer 34A on the first circuit layer 32A. The second isolation layer, as shown in FIGS. 2J to 2M and discussed in accompanying text, will is used to separate features of the second circuit layer with features of the third circuit layer. Depending on circumstances, however, the second isolation layer may have identical, similar, or different in composition and/or properties with respect to the first isolation layer.

FIGS. 2J to 2L show steps analogous to those depicted in FIGS. 2D to 2F. For example, FIG. 2J, depicts the deposition of the second optional seed region 39B is deposited on the portion of the surface of the second circuit layer 32B that is left uncovered by first isolation layer 34 due to the presence of the first through-hole 37A. FIG. 2K depicts the deposition of a third circuit layer of an initial third circuit layer microstructure 32C′ on the second isolation layer 34B. FIG. 2L depicts the transformation of initial third circuit layer microstructure 32C′ into one that renders the third circuit layer suitable for forming circuit features therein. A substrate 30 having three circuit layers, each having circuits formed therein is shown in FIG. 2M. Effectively, then, the three-dimensional circuit structure 30 shown in FIG. 2M has three times the feature density (transistor density) from that obtained with single-layer conventional lithography.

### Variations on the Invention

It will be apparent to those of ordinary skill in the art that the invention may be embodied in various forms. For example, high-power CO₂ lasers may be used to generate an image having a substantially Gaussian intensity profile, which, in turn, is scanned across a surface of a substrate to effect thermal processing, e.g., melt or non-melt processing, of the substrate surface to bring about the desired phase transformation and circuit layers with appropriate electronic properties. Radiation sources other than CO₂ lasers having a wavelength, λ, of 10.6 μm in the infrared region may be used as well. Acceptable radiation sources must be able to produce radiation of a wavelength absorbable by the material whose microstructure is to be transformed in a manner such that precise control over the processing temperatures may be achieved. Such radiation sources may generate coherent and/or incoherent light.

In addition, the stage may include different components to carry out different functions to ensure that any radiation beam used to carry out the invention is imaged onto the material whose microstructure is to be transformed with great positional and angular control. For example, an alignment system may be included to position the substrate on the stage at a variable orientation angle relative to the surface normal. In such a case, the substrate movement and alignment may be independently controlled.

Additional variations of the present invention will be apparent to those of ordinary skill in the art. For example, while 3-D circuit structures having two or three circuit layers having similar circuit features deposited therein have been described in detail, inventive circuit structures may include more than three layers or layers having dissimilar circuit features therein. Similarly, while the exemplary process described above is generally applicable to circuit layers of silicon, other semiconductors may be used.

In addition, upon routine experimentation, those skilled in the art may find that the inventive system may be adapted from existing laser annealing equipment. Auxiliary subsystems known in the art may be used to stabilize the position and the width of the laser beam relative to the relay. Those of ordinary skill in the art will recognize that care must be taken to address to certain operational issues relating to the practice of the invention using powerful lasers to realize the full benefit of the invention.

It is to be understood that, while the invention has been described in conjunction with the preferred specific embodiments thereof, the foregoing description is intended to illustrate and not limit the scope of the invention. Any aspects of the invention discussed herein may be included or excluded as appropriate. Other aspects, advantages, and modifications within the scope of the invention will be apparent to those skilled in the art to which the invention pertains.

What is claimed is:

1. A process for forming a three-dimensional circuit on a substrate, the process comprising:
providing the substrate, the substrate comprising
a first circuit layer,
a second circuit layer,
a seed region, and
an isolating layer interposed between the first and second circuit layers and including a through-hole disposed therethrough,
wherein the second circuit layer communicates with the first circuit layer via the through-hole, and wherein the seed region is disposed within the through-hole and has a crystalline surface, and wherein the second circuit layer includes a microstructure that exhibits electronic properties unsuitable for forming circuit features therein; and
heating the second circuit layer no higher than a submelt temperature thereof in order to initiate and propagate crystal growth from the seed region, thereby transforming the initial microstructure of the second circuit layer into a transformed microstructure that exhibits electronic properties suitable for forming circuit features therein.

2. The process of claim 1, wherein the initial microstructure is amorphous and the transformed microstructure is crystalline.

3. The process of claim 1 wherein the transformed microstructure comprises a polycrystalline microstructure having a grain size between about 10 micrometers and 1 millimeter.

4. The process of claim 1 wherein the transformed microstructure comprises a polycrystalline microstructure having a grain size of at least 1 millimeter.

5. The process of claim 1 wherein providing the substrate includes the steps of
forming the first circuit layer,
forming the isolating layer on the first circuit layer,
forming the through-hole through the isolating layer to expose a surface of the first circuit layer, and
forming the second circuit layer over the isolating layer.

6. The process of claim 5 wherein providing the substrate further includes forming the seed region within the through-hole before forming the second circuit layer.

7. The process of claim 1 wherein heating the second circuit layer is performed by directing a radiation beam at the second circuit layer.

8. The process of claim 7 wherein the radiation beam comprises a coherent radiation.

9. The process of claim 7 wherein the radiation beam comprises an incoherent radiation.

10. The process of claim 7 wherein the radiation beam comprises a continuous beam.

11. The process of claim 7 wherein the radiation beam comprises a pulsed beam.

12. The process of claim 7 wherein the radiation beam is directed at the second circuit layer at an incidence angle equal to a Brewster's angle for the substrate.

13. The process of claim 7 wherein the radiation beam is polarized.

14. The process of claim 7 wherein the radiation beam forms an image on the second circuit layer, the image being characterized by an intensity profile, the profile being a distribution of an integrated radiation intensity along a dimension of the image, wherein the intensity profile is non-uniform in that the intensity profile consists of a first portion and a second portion wherein each portion is characterized by a different intensity profile.

15. The process of claim 14 wherein the first portion is characterized by a uniform intensity profile.
